(19) United States
(12) Patent Application Publication
(10) Pub. No.: US 2023/0420392 A1
(43) Pub. Date: Dec. 28, 2023

(54) SEMICONDUCTOR DEVICE AND METHODS OF MANUFACTURING

(71) Applicant: Taiwan Semiconductor Manufacturing Company, Ltd., Hsinchu (TW)

(72) Inventors: Yu-Lun LU, Hsinchu City (TW); Tsung-Chieh TSAI, Chu-Bei City (TW); Kong-Beng THEI, Pao-Shan Village (TW); Yu-Chang JONG, Hsinchu City (TW)

(21) Appl. No.: 17/809,432

(22) Filed: Jun. 28, 2022

(51) Int. Cl. H01L 23/58; H01L 23/00

(52) U.S. Cl. CPC H01L 23/585; H01L 24/08; H01L 23/564; H01L 23/562; H01L 24/80; H01L 2224/08145; H01L 2224/80895; H01L 2224/80896

(57) ABSTRACT

Some implementations described herein provide techniques and apparatuses for a stacked-die structure including a first integrated circuit device over a second integrated circuit device, where an operating voltage of the first integrated circuit device is different relative to an operating voltage of the second integrated circuit device. The first integrated circuit device includes a first portion of a seal ring structure of the stacked-die structure. The first portion includes an interconnect structure that connects a backside redistribution layer of the first integrated circuit device with first metal layers of the first integrated circuit device. The seal ring structure including the interconnect structure eliminates the use of diodes and electrically isolates well structures of the first integrated circuit device to reduce leakage paths relative to a stacked-die structure having a seal ring structure including a diode within the stacked-die structure. Furthermore, use of the interconnect structure as part of the seal ring structure substantially eliminates moisture and/or cracking from penetrating the stacked-die structure.

### BACKGROUND

A stacked-die structure, such as wafer-on-wafer (WoW) semiconductor package, may include two or more integrated circuit (IC) dies that are stacked vertically and bonded along a bond line. To address a propagation of cracks during a dicing or sawing operation or a penetration of moisture to the circuitry of the two or more IC dies, a seal ring structure may be included near edges of the two IC dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of an example implementation of a seal ring structure described herein.

FIG. 3 is a diagram of an example implementation described herein.

FIGS. 4A-4F are diagrams of an example implementation described herein.

FIG. 5 is a diagram of example components of one or more devices of FIG. 1 described herein.

FIG. 6 is a flowchart of an example process associated with fabricating a seal ring structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a stacked-die structure may include two or more integrated circuit (IC) dies that are stacked and bonded along a bond line. The two or more IC dies may be different types of devices and have different operating voltages. Additionally, the stacked-die structure may include a seal ring structure located near edges of the two or more IC dies. The seal ring structure, which may include integrated circuitry such as diodes, may reduce a likelihood of chipping and/or cracking of the two or more IC dies during a sawing operation. The seal ring structure may also reduce a likelihood of moisture from penetrating into the two or more IC dies during a qualification process (e.g., a high accelerated steam testing, or HAST testing) to prevent delamination, corrosion, or other damage within the two or more IC dies.

In a case where operating voltages of the devices are different, shorting and/or electrical leakage within the WoW semiconductor package may occur. Structures included within the seal ring structure intended to limit the shorting and/or the electrical leakage, such as diodes, may be ineffective.

Some implementations described herein provide techniques and apparatuses for a stacked-die structure including a first IC die over a second IC die, where an operating voltage of the first IC die is different relative to an operating voltage of the second IC die. The first IC die includes a first portion of a seal ring structure of the stacked-die structure. The first portion includes an interconnect structure (e.g., a backside through silicon via) that connects a backside redistribution layer of the first IC die with first metal layers of the first IC die.

The seal ring structure including the interconnect structure eliminates the use of diodes and electrically isolates well structures of the first IC die to reduce leakage paths within the stacked-die structure relative to a seal ring structure including a diode. Furthermore, use of the interconnect structure as part of the seal ring structure provides for a physical barrier that substantially eliminates moisture and/or cracking from penetrating the stacked-die structure.

In this way, a likelihood of leakage within the stacked-die structure may be reduced relative to a stacked-die structure having a seal ring structure including a diode to improve an electrical performance of the stacked-die structure. Additionally, a physical barrier formed using the interconnect structure as part of the seal ring structure substantially eliminates moisture and/or cracking from penetrating the stacked-die structure to improve a yield and/or a reliability of the stacked-die structure.

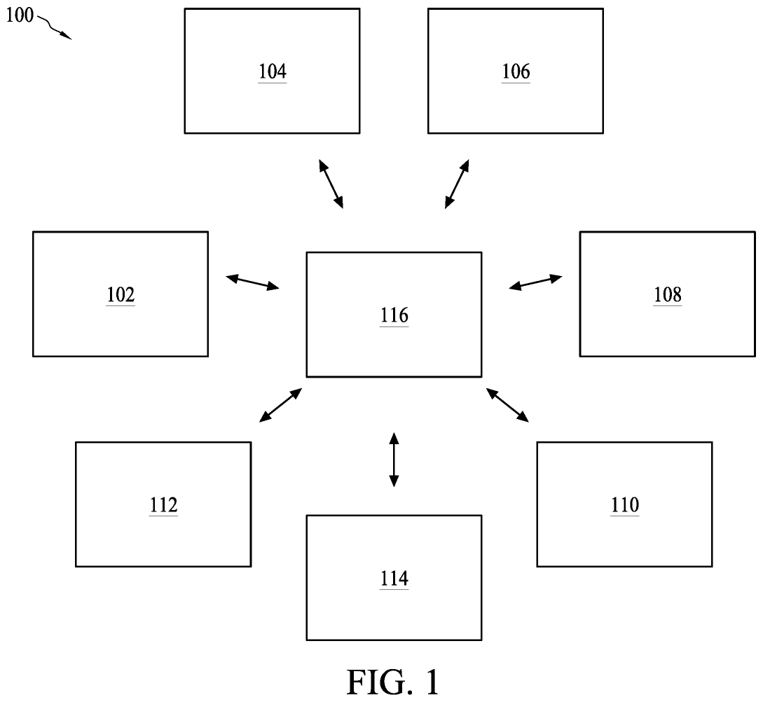

FIG. 1 is a diagram of an example environment 100 in which systems and/or methods described herein may be implemented. As illustrated in FIG. 1, environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions. In some implementations, the etch tool 108 includes a plasma-based asher to remove a photoresist material.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more semiconductor substrate (e.g., two or more wafers, or two or more semiconductor dies) together. For example, the bonding tool 114 may include a eutectic bonding tool that is capable of forming a eutectic bond between two or more semiconductor substrates In these examples, the bonding tool 114 may heat the two or more semiconductor substrates to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

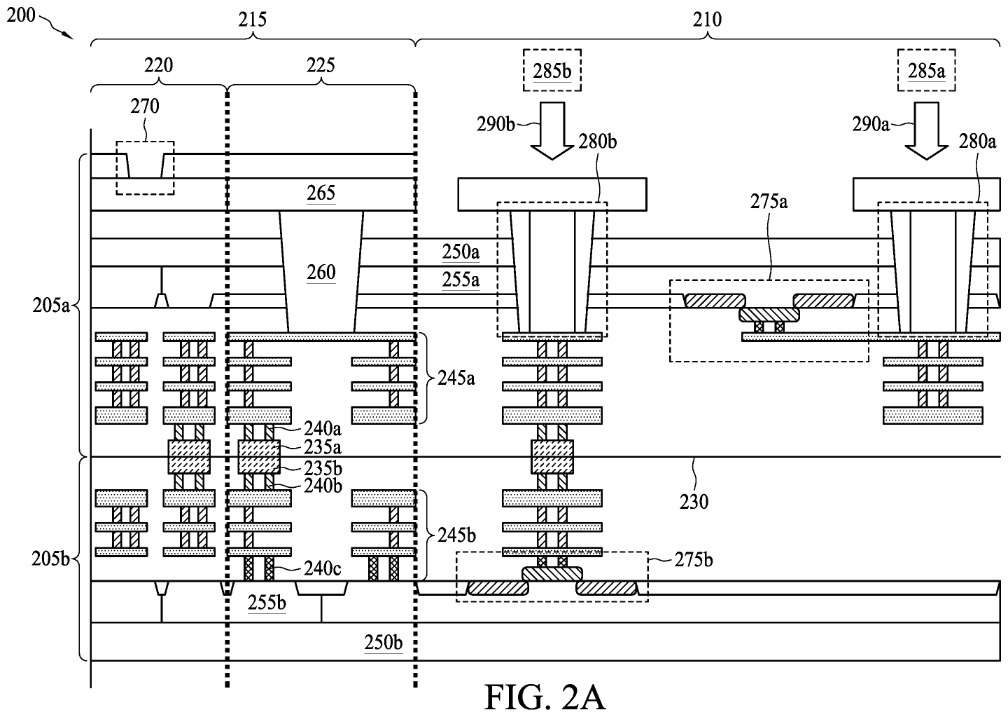

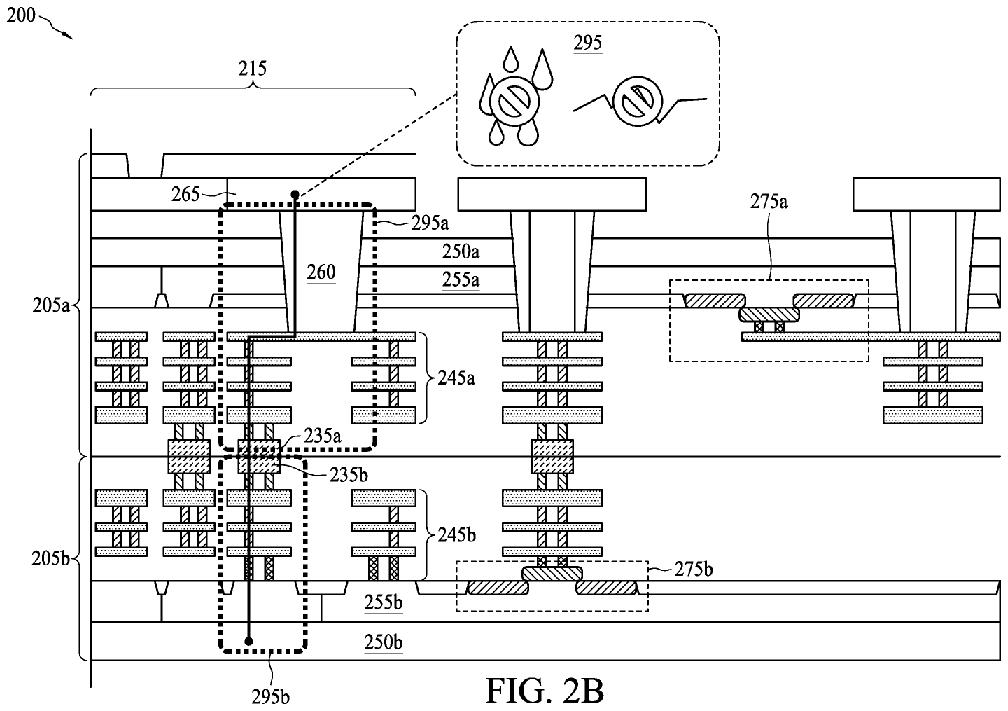

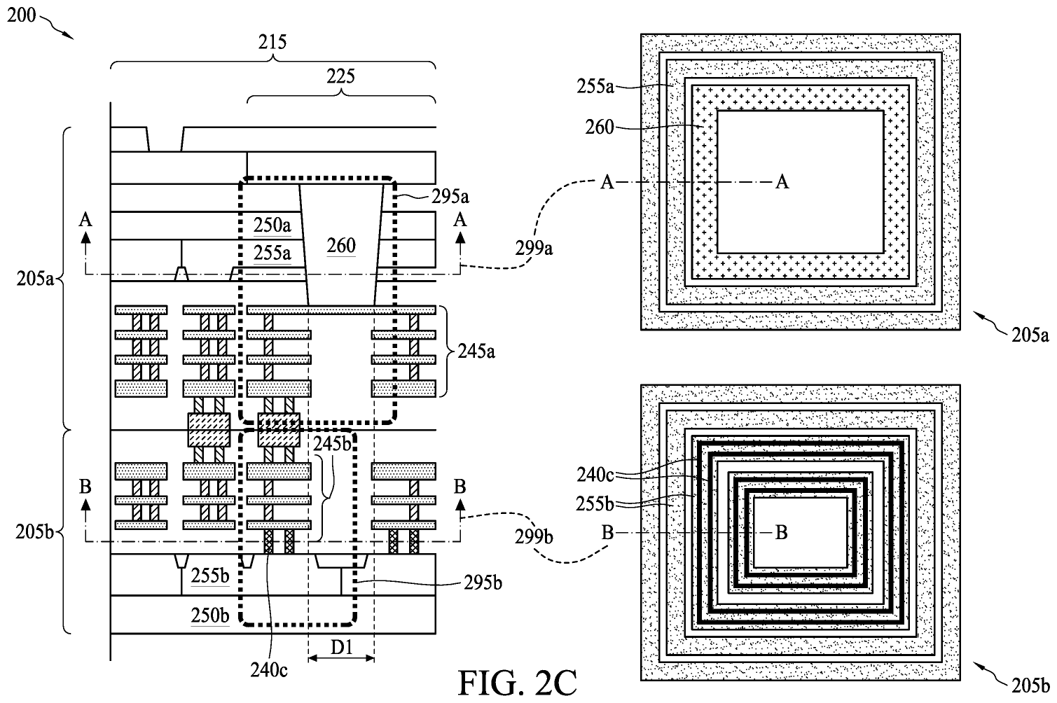

As described in connection with FIGS. 2A-6 and elsewhere herein, the semiconductor processing tools 102-114 may perform a combination of operations to form a semiconductor structure (e.g., a stacked-die structure) including a seal ring structure. As an example, the series of operations includes forming, over a first substrate, a first substructure of a first portion of a seal ring structure, where forming the first substructure comprises forming the first substructure over a first surface of the first substrate. The series of operations includes forming, over a second substrate, a first substructure of a second portion of the seal ring structure. The series of operations includes forming, over the first substructure, a second substructure of the first portion of the seal ring structure. The series of operations includes forming, over the second substrate, a second substructure of the second portion of the seal ring structure. The series of operations includes joining the second substructure of the first portion of the seal ring structure to the second substructure of the second portion of the seal ring structure. The series of operations includes forming, through the first substrate, an interconnect structure that connects to the first substructure of the first portion of the seal ring structure, where forming the interconnect structure comprises forming the interconnect structure from a second surface of the first substrate that is opposite the first surface.

The number and arrangement of devices illustrated in FIG. 1 are provided as one or more examples. In practice, there may be additional devices, fewer devices, different devices, or differently arranged devices than those illustrated in FIG. 1. Furthermore, two or more devices illustrated in FIG. 1 may be implemented within a single device, or a single device illustrated in FIG. 1 may be implemented as multiple, distributed devices. Additionally, or alternatively, a set of devices (e.g., one or more devices) of environment 100 may perform one or more functions described as being performed by another set of devices of environment 100.

FIGS. 2A-2C are diagrams of an example implementation 200 of a seal ring structure described herein. Features described in the example implementation 200 may be formed using one or more of the semiconductor processing tools 102-114 described in connection with FIG. 1.

FIG. 2A illustrates a side view of an integrated circuit (IC) die 205a bonded to an IC die 205b. In some implementations, the IC die 205a bonded to the IC die 205b correspond to a stacked-die structure (e.g., a WoW semiconductor package). The stacked-die structure may include a device region 210 (e.g., active integrated circuitry) adjacent to an edge region 215 (e.g., inactive integrated circuitry). The edge region 215 may include a scribe line dummy bar region 220 and a seal ring region 225.

The IC die 205a may be bonded to the IC die 205b along a bond line 230. Within the seal ring region 225, the bond line 230 may include a eutectic bond between a surface of a hybrid bond layer structure 235a of the IC die 205a and a surface of a hybrid bond layer structure 235b of the IC die 205b. The hybrid bond layer structure 235a and/or the hybrid bond layer structure 235b may include a conductive material, such as an aluminum (Al) material, a copper (Cu) material, a titanium (Ti) material, a silver (Ag) material, a gold (Au) material, or a nickel (Ni) material, among other examples.

As illustrated in FIG. 2A, the IC die 205a includes a contact structure 240a (e.g., a hybrid bond contact structure) and a plurality of metal layers 245a. The plurality of metal layers 245a may include, for example, a metal 1 (M1) layer, a top metal (TME) layer, and/or intermetal (IM) layers that are electrically and/or mechanically connected by interconnect structures. The contact structure 240a and/or the plurality of metal layers 245a may include a conductive material, such as an aluminum (Al) material, a copper (Cu) material, a titanium (Ti) material, a silver (Ag) material, a gold (Au) material, or a nickel (Ni) material, among other examples.

The IC die 205a further includes a substrate 250a and a well structure 255a. In some implementations, the substrate 250a corresponds to a p-type substrate (e.g., a silicon substrate doped with a first concentration of boron (B) or gallium (Ga), among other examples). In some implementations, the well structure 255a corresponds to a p-type well structure (e.g., a region of the substrate 250a doped with a second concentration of boron (B), or gallium (Ga), among other examples). In some implementations, the dopants and/or respective concentrations of the dopants of the substrate 250a and the well structure 255a are different.

The IC die 205a includes an interconnect structure 260 that is mechanically connected to the plurality of metal layers 245a. As illustrated in FIG. 2A, the interconnect structure 260 passes through (e.g., penetrates) the substrate 250a and the well structure 255a. In some implementations, the interconnect structure 260 corresponds to a backside through silicon via (BTSV) interconnect structure. The interconnect structure 260 may include a dielectric material (e.g., an oxide material, among other examples) that electrically isolates the substrate 250a and/or the well structure 255a from the plurality of metal layers 245a. The IC die 205a further includes a redistribution layer 265. The redistribution layer 265 may include a conductive material, such as an aluminum (Al) material, a copper (Cu) material, a titanium (Ti) material, a silver (Ag) material, a gold (Au) material, or a nickel (Ni) material, among other examples.

In some implementations, the IC die 205a may include additional layers, such as a passivation layer (e.g., an aluminum oxide (Al₂O₃) layer, among other examples) having a ditch structure 270 within the scribe line dummy bar region 220. The ditch structure 270 may serve as a barrier to air or water from entering or escaping the IC die 205a.

The IC die 205b, as illustrated in FIG. 2A, includes a contact structure 240b (e.g., a hybrid bond contact structure) and a plurality of metal layers 245b. The plurality of metal layers 245b may include, for example, a metal 1 (M1) layer, a top metal (TME) layer, and/or intermetal (IM) layers that are electrically and/or mechanically connected by interconnect structures. The hybrid bond contact structure 240b and/or the plurality of metal layers 245b may include a conductive material, such as an aluminum (Al) material, a copper (Cu) material, a titanium (Ti) material, a silver (Ag) material, a gold (Au) material, or a nickel (Ni) material, among other examples.

The IC die 205b further includes a substrate 250b and a well structure 255b. In some implementations, the substrate 250b corresponds to a p-type substrate (e.g., a silicon substrate doped with a first concentration of boron (B) or gallium (Ga), among other examples). In some implementations, the well structure 255b corresponds to a p-type well structure (e.g., a region of the substrate 250b doped with a second concentration of boron (B), or gallium (Ga), among other examples). In some implementations, the dopants and/or respective concentrations of the dopants of the substrate 250b and the well structure 255b are different.

As illustrated in FIG. 2A, the device region 210 includes active integrated circuitry. For example, and as illustrated in FIG. 2A, the IC die 205a includes a transistor structure 275a and the IC die 205b includes a transistor structure 275b. Furthermore, within the device region 210 the IC die 205a includes an interconnect structure 280a that is electrically connected to the integrated circuitry (e.g., the transistor structure 275a, among other examples) of the IC die 205a and an interconnect structure 280b that is electrically connected to the integrated circuitry (e.g., the transistor structure 275b, among other examples) of the IC die 205b. The interconnect structure 280a and/or the interconnect structure 280b may each correspond to a backside through silicon via (BTSV) structure including a backside redistribution via (RVB) passing through a central axis of the BTSV.

The interconnect structures 280a and/or 280b may include a combination of materials. For example, outer perimeters or edge regions of the interconnect structures 280a and/or 280b may include a dielectric material such as a silicon-dioxide (Si₂O₃) material, among other examples. Core or central regions of the interconnect structures 280a and/or 280b may include a conductive material, such as an aluminum (Al) material, a copper (Cu) material, a titanium (Ti) material, a silver (Ag) material, a gold (Au) material, or a nickel (Ni) material, among other examples.

In some implementations, the integrated circuitry of the IC die 205a and the integrated circuitry of the IC die 205b may be configured to operate at different voltages. For example, the integrated circuitry of the IC die 205a (e.g., the well structure 255a and the transistor structure 275a of the device region 210, among other examples) may be configured to operate in a range of approximately 0.9 volts (V) to approximately 5.0 V. In such a case, a voltage source 285a may provide a voltage 290a in a range of approximately 0.9 volts (V) to approximately 5.0 V to the integrated circuitry of the IC die 205a. Additionally, or alternatively, the integrated circuitry of the IC die 205b (e.g., the well structure 255b and the transistor structure 275b of the device region 210, among other examples) may be configured to operate in a range of approximately 8.0 V to approximately 28.0 V. In such a case, a voltage source 285b may provide a voltage 290b in a range of approximately 5.0 volts (V) to approximately 28.0 V to the integrated circuitry of the IC die 205b. However, other values and ranges for operating voltages of the integrated circuitries of the IC die 205a and the IC die 205b are within the scope of the present disclosure.

FIG. 2B illustrates a side view of a seal ring structure 295 formed in the stacked-die structure (e.g., the IC die 205a bonded to the IC die 205b). The seal ring structure 295 includes a portion 295a (e.g., a first portion). The portion 295a includes the interconnect structure 260 passing through the substrate 250a (e.g., a first substrate) and the well structure 255a (e.g., a first well structure) of the IC die 205a (e.g., a first IC die). As illustrated FIG. 2B, the interconnect structure 260 is part of a mechanical connection from the redistribution layer 265 to the substrate 250b. The portion 295a includes the plurality of metal layers 245a (e.g., a first plurality of metal layers) below the interconnect structure 260. The portion 295a includes the hybrid bond layer structure 235a (e.g., a first hybrid bond layer) below the plurality of metal layers 245a.

The seal ring structure 295 of FIG. 2B further includes a portion 295b (e.g., a second portion). The portion 295b includes the plurality of metal layers 245b (e.g., a second plurality of metal layers) above the substrate 250b (e.g., a second substrate) and the well structure 255b (e.g., a second well structure) of the IC die 205b (e.g., a second IC die). The portion 295b further includes the hybrid bond layer structure 235b (e.g., a second hybrid bond layer) above the plurality of metal layers 245b. In some implementations, and as illustrated in FIG. 2B, the second hybrid bond layer structure 235b joins with the first hybrid bond layer structure 235a to complete the seal ring structure 295 and substantially eliminate moisture and/or cracks from penetrating through the seal ring structure 295 to integrated circuitry (e.g., the transistor structure 275a and/or the transistor structure 275b, among other examples) adjacent to the seal ring structure 295.

As an example, substantial elimination of the moisture may correspond to satisfying a threshold corresponding to a high accelerated steam test (HAST) qualification process. Additionally, or alternatively, substantial elimination of moisture may correspond to satisfying a threshold corresponding to a customer or environmental specification (e.g., an environmental specification for an automotive application, among other examples).

As an example, substantial elimination of cracks may correspond to satisfying a threshold corresponding to a drop-testing qualification process. Additionally, or alternatively, substantial elimination of cracks may correspond to satisfying a threshold corresponding to a customer or environmental specification (e.g., a vibration or acceleration specification for an aircraft application, among other examples).

Additionally, or alternatively, the IC die 205a (e.g., the first IC die) includes the portion 295a (e.g., the first portion) of the seal ring structure 295 at an edge (e.g., the edge region 215) of the IC die 205a. The IC die 205a includes the well structure 255a that is electrically isolated from the seal ring structure 295, where the seal ring structure 295 passes through the well structure 255a. The IC die 205a further includes integrated circuitry (e.g., first integrated circuitry corresponding to the well structure 255a and the transistor structure 275a, among other examples) adjacent to the portion 295a. The integrated circuitry of the IC die 205a may be configured to function at an operating voltage (e.g., a first operating voltage) that is included in a range of approximately 0.9V to approximately 5.0V as described in connection with FIG. 2B.

Additionally, or alternatively, the IC die 205b (e.g., the second IC die) is located below the IC die 205a. The IC die 205b includes the portion 295b (e.g., the second portion) of the seal ring structure 295 at an edge of the IC die 205b (e.g., the edge region 215) below the portion 295a. The IC die 205b further includes integrated circuitry (e.g., second integrated circuitry corresponding to the well structure 255b and the transistor structure 275b, among other examples) adjacent to the portion 295b and below the integrated circuitry of the IC die 205a. The integrated circuitry of the IC die 205b may be configured to function at an operating voltage that is different relative to the operating voltage of the integrated circuitry of the IC die 205a. For example, the integrated circuitry of the IC die 205b may be configured to operate at an operating voltage (e.g., a second operating voltage) that is included in a range of approximately 8.0V to approximately 28.0V.

The seal ring structure 295 including the interconnect structure 260 eliminates the use of diodes and electrically isolates the well structure 255a of the IC die 205a to substantially reduce leakage and/or shorting between integrated circuitry of the IC die 205a and the IC die 205b. In some implementations, substantially reducing leakage and/or shorting may correspond to eliminating leakage and/or shorting through isolating the integrated circuitry of the IC die 205a from the integrated circuitry of the IC die 205b.

Furthermore, use of the interconnect structure 260 as part of the seal ring structure 295 provides for a physical barrier that reduces a likelihood of moisture and/or cracking from penetrating into the IC die 205a and/or the IC die 205b (e.g., the stacked-die structure).

FIG. 2C illustrates additional aspects of the implementation 200. As illustrated in the side view of FIG. 2C (e.g., the left portion of FIG. 2C), the stacked-die structure (e.g., the IC die 205a over the IC die 205b) may include one or more dimensional and/or geometric properties. For example, a width D1 of the interconnect structure 260 may be included in a range of approximately 2.50 microns to approximately 3.05 microns. If the width D1 is less than approximately 2.50 microns, a fill or deposition process used to form the interconnect structure 260 may create voids and/or defects within the interconnect structure 260. If the width D1 is greater than approximately 3.05 microns, area may be wasted and a cost of the stacked-die structure may be increased. However, other values and ranges for the width D1 are within the scope of the present disclosure.

In some implementations, the interconnect structure 260 corresponds to a through vertical interconnect access (via) structure. As shown in the side view of FIG. 2C, the interconnect structure 260 may include a tapered cross-sectional shape. In some implementations, the interconnect structure 260 connects to a top metal layer of the plurality of metal layers 245a.

The right portion of FIG. 2C illustrates top views of a section 299a of IC die 205a and top view of a section 299b of IC die 205b. As illustrated in the top view corresponding to the section 299a, the interconnect structure 260 may correspond to a ring-shaped interconnect structure and the well structure 255a may correspond to a ring-shaped well structure. Furthermore, and as shown in the corresponding top view for the section 299b, the well structure 255b may correspond to a ring-shaped well structure and the contact structures 240c may correspond to ring-shaped contact structures. The contact structures 240c are between a top surface of the well structure 255b and the plurality of metal layers 245b.

The structure (e.g., a semiconductor structure) illustrated in the views of FIG. 2C includes the IC die 205a (e.g., a first IC die). The IC die 205a includes the substrate 250a (e.g., a first substrate) and the well structure 255a (e.g., a first ring-shaped well structure below the first substrate). The IC die 205a further includes the portion 295a (e.g., a first portion of the seal ring structure 295). The portion 295a includes the interconnect structure 260 (e.g., a ring-shaped through-via structure). In some implementations, and as shown in FIG. 2C, the interconnect structure 260 penetrates through the substrate 250a and the well structure 255a.

The structure illustrated in the views of FIGS. 2C further includes the IC die 205b (e.g., a second IC die) bonded to the IC die 205a below the first portion 295a. The IC die 205b includes the substrate 250b (e.g., a second substrate) and the well structure 255b (e.g., a second ring-shaped well structure above the second substrate). The IC die 205b includes the portion 295b (e.g., a second portion of the seal ring structure 295). The portion 295b includes the contact structures 240c (e.g., ring-shaped contact structures). In some implementations, and as shown in FIG. 2C, the contact structures 240c connect to the well structure 255b.

As indicated above, FIGS. 2A-2C are provided as examples. Other examples may differ from what is described with regard to FIGS. 2A-2C.

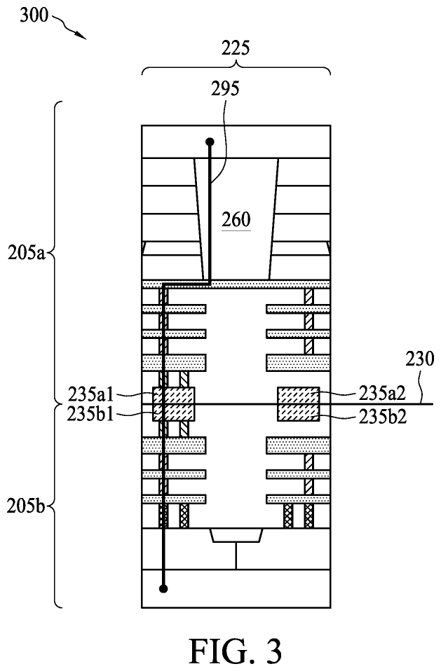

FIG. 3 is a diagram of an example implementation 300 herein. FIG. 3 includes a side view of an implementation including one or more features of the semiconductor structure (e.g., a stacked-die structure including the IC die 205a over the IC die 205b) described in connection with FIGS. 1 and 2A-2C.

As illustrated in FIG. 3, the IC die 205a and the IC die 205b are in a joined (e.g., stacked) state. In some implementations, and as illustrated in FIG. 3, the IC die 205a and the IC die 205b are joined after having been diced (e.g., removed or sawed-off) from respective semiconductor substrates (e.g., silicon wafers, among other examples) that include the IC dies 205a and 205b. The semiconductor structure includes the seal ring structure 295 within the seal ring region 225 (including the interconnect structure 260).

A scribe line dummy bar region (e.g., the scribe line dummy bar region 220) is absent from the semiconductor structure (e.g., the scribe line dummy bar region 220 may have been removed during the dicing process). To compensate for the absence of the scribe line dummy bar region (and/or hybrid bond layer structures) that may have been within the scribe line dummy bar region of the IC die 205a, the IC die 205a may include a dummy hybrid bond layer structure 235a2 in addition to the hybrid bond layer structure 235a1 along the bond line 230. To compensate for the absence of the scribe line dummy bar region (and/or hybrid bond layer structures) that may have been within the scribe line dummy bar region of the IC die 205b, the IC die 205b may include a dummy hybrid bond layer structure 235b2 in addition to the hybrid bond layer structure 235b1 along the bond line 230.

As indicated above, FIG. 3 is provided as an example. Other examples may differ from what is described with regard to FIG. 3.

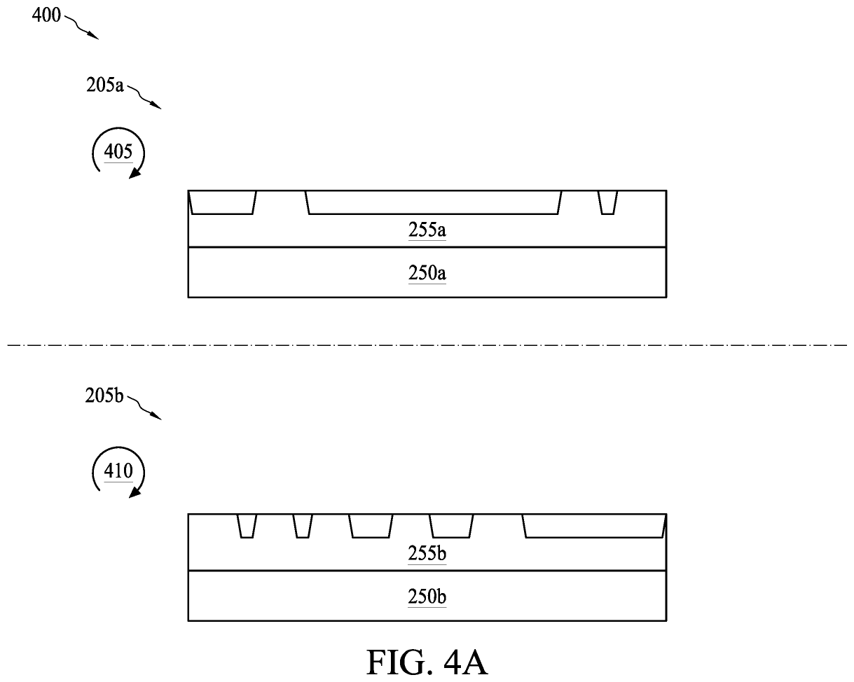

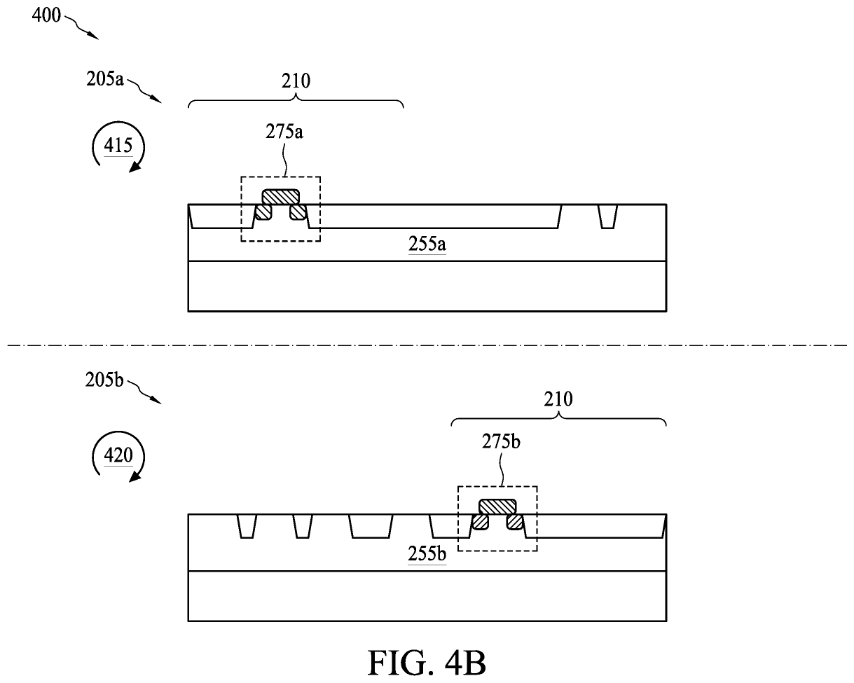

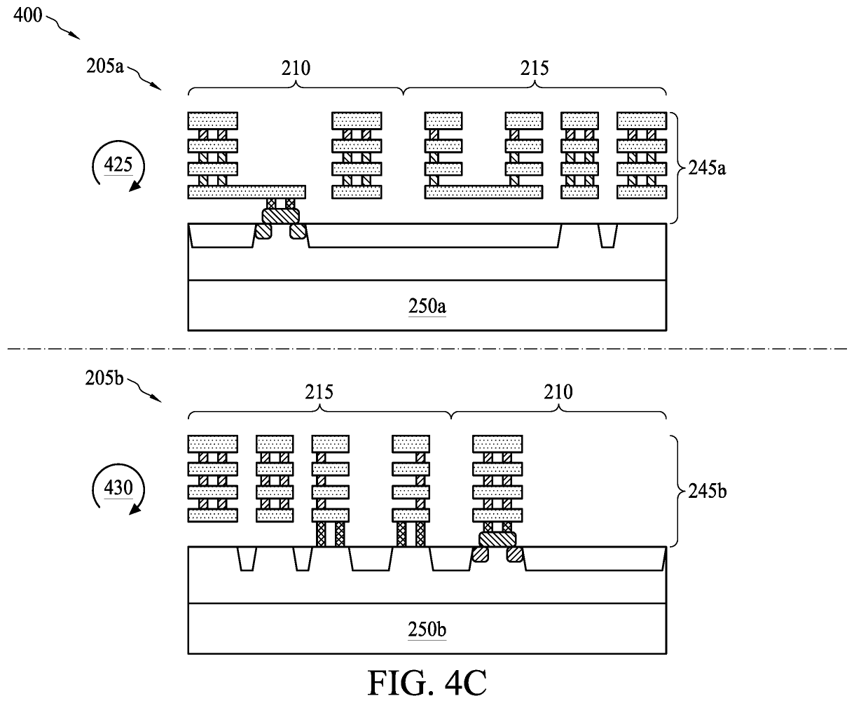

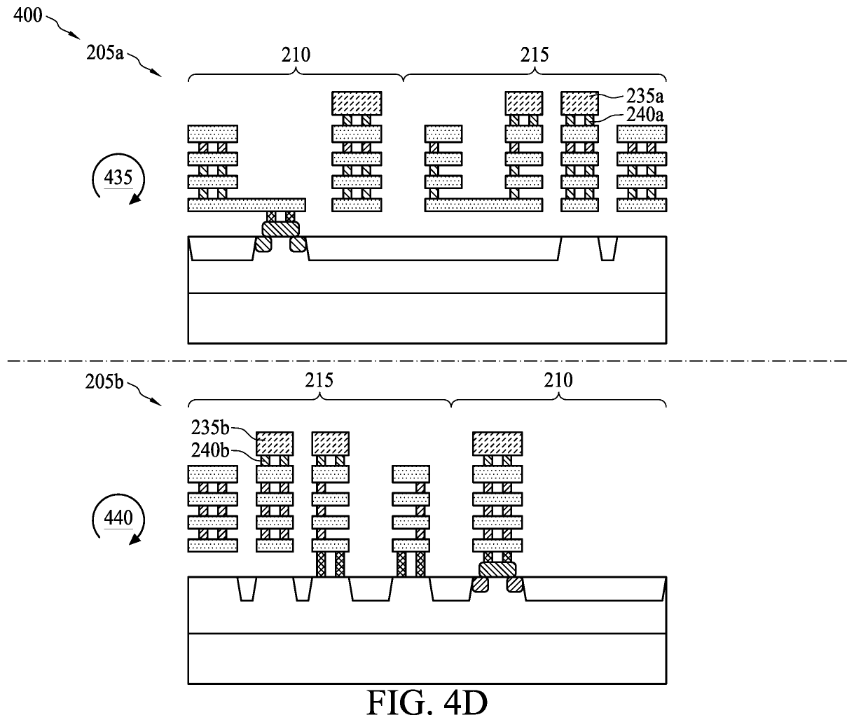

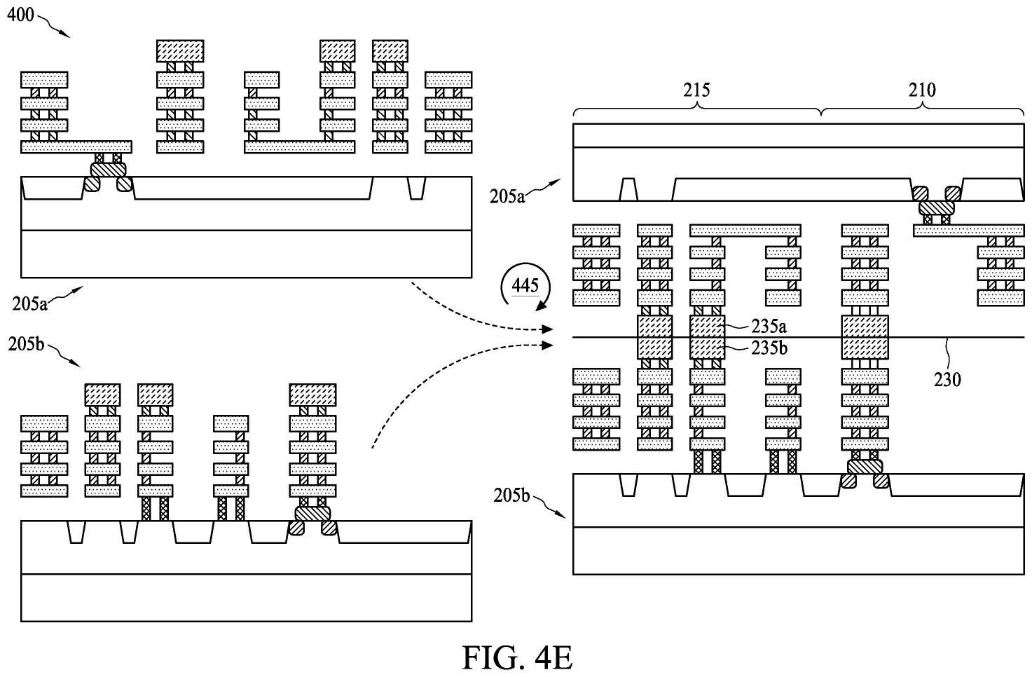

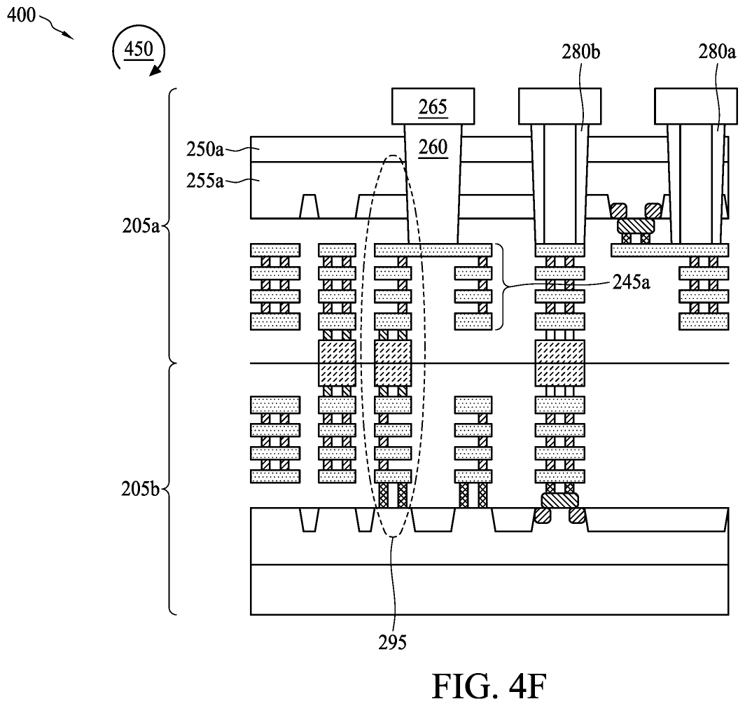

FIGS. 4A-4F are diagrams of an example implementation 400 described herein. The implementation 400 includes a series of operations that may be performed by one or more of the semiconductor processing tools 102-114 to form a stacked-die structure including the IC die 205a bonded to the IC die 205b. In some implementations, the series of operations corresponds to a wafer-on-wafer (WoW) packaging process.

As illustrated in FIG. 4A, one or more of the semiconductor processing tools 102-114 (e.g., one or more of the deposition tool 102, the exposure tool 104, the developer tool 106, or the etch tool 108, among other examples) may perform a series of operations 405 to form the well structure 255a over the substrate 250a. Additionally, or alternatively, one or more of the semiconductor processing tools 102-114 (e.g., one or more of the deposition tool 102, the exposure tool 104, the developer tool 106, or the etch tool 108, among other examples) may perform a series of operations 410 to form the well structure 255b over the substrate 250b.

As illustrated in FIG. 4B, one or more of the semiconductor processing tools 102-114 (e.g., one or more of the deposition tool 102, the exposure tool 104, the developer tool 106, or the etch tool 108, among other examples) may perform a series of operations 415 to form the transistor structure 275a as part of integrated circuitry within the device region 210 of the IC die 205a. Additionally, or alternatively, one or more of the semiconductor processing tools 102-114 (e.g., one or more of the deposition tool 102, the exposure tool 104, the developer tool 106, or the etch tool 108, among other examples) may perform a series of operations 420 to form the transistor structure 275b as part of integrated circuitry within the device region 210 of the IC die 205b.

As illustrated in FIG. 4C, one or more of the semiconductor processing tools 102-114 (e.g., one or more of the deposition tool 102, the exposure tool 104, the developer tool 106, or the etch tool 108, among other examples) may perform a series of operations 425 to form the a plurality of metal layers 245a within the device region 210 and the edge region 215 of the IC die 205a. In some implementations, a portion of the plurality of metal layers 245a corresponds to a substructure of a seal ring structure (e.g., a first substructure of the portion 295a of the seal ring structure 295). Additionally, or alternatively, one or more of the semiconductor processing tools 102-114 (e.g., one or more of the deposition tool 102, the exposure tool 104, the developer tool 106, or the etch tool 108, among other examples) may perform a series of operations 430 to form the plurality of metal layers 245b within the device region 210 and the edge region 215 of the IC die 205b. In some implementations, a portion of the plurality of metal layers 245b corresponds to a substructure of a seal ring structure (e.g., a substructure of the portion 295b of the seal ring structure 295).

As illustrated in FIG. 4D, one or more of the semiconductor processing tools 102-114 (e.g., one or more of the deposition tool 102, the exposure tool 104, the developer tool 106, or the etch tool 108, among other examples) may perform a series of operations 435 to form one or more of the hybrid bond layer structure 235a and the contact structure 240a within the device region 210 and the edge region 215 of the IC die 205a. In some implementations, the hybrid bond layer structure 235a and the contact structure 240a correspond to a substructure of a seal ring structure (e.g., a second substructure of the portion 295a of the seal ring structure 295).

Additionally, or alternatively, one or more of the semiconductor processing tools 102-114 (e.g., one or more of the deposition tool 102, the exposure tool 104, the developer tool 106, or the etch tool 108, among other examples) may perform a series of operations 440 to form one or more of the hybrid bond layer structure 235b and the hybrid bond contact structure 240b within the device region 210 and the edge region 215 of the IC die 205b. In some implementations, the hybrid bond layer structure 235b and the hybrid bond contact structure 240b correspond to a substructure of a seal ring structure (e.g., a second substructure of the portion 295b of the seal ring structure 295).

As illustrated in FIG. 4E, one or more of the semiconductor processing tools 102-114 (e.g., the bonding tool 114, among other examples) may perform a series of operations 445 to join the IC die 205a and the IC die 205b. The series of operations 445 may include a eutectic bonding operation to bond the IC die 205a and the IC die 205b along the bond line 230. Joining the IC die 205a and the IC die 205b may include joining surfaces of the hybrid bond layer structure 235a and the hybrid bond layer structure 235b (e.g., joining substructures of the portions 295a and 295b). Joining the IC die 205a and the IC die 205b may include inverting the IC die 205a to align the device region 210 and the edge region 215 across the IC dies 205a and 205b.

As illustrated in FIG. 4F, one or more of the semiconductor processing tools 102-114 (e.g., the bonding tool 114, among other examples) may perform a series of operations 450 to form the interconnect structure 260 and the redistribution layer 265. Forming the interconnect structure 260 may include forming the interconnect structure 260 through a backside of the substrate 250a to mechanically connect the interconnect structure 260 to the plurality of metal layers 245a (e.g., a substructure of the portion 295a of the seal ring structure 295).

In some implementations, forming the interconnect structure 260 includes one or more of the semiconductor processing tools 102-114 (e.g., the exposure tool 104, the developer tool 106, and/or the etch tool 108, among other examples) forming a through-hole that passes through the substrate 250a and the well structure 255a to expose the first plurality of metal layers 245a. Forming the interconnect structure 260 may further include one or more of the semiconductor processing tools 102-114 (e.g., the deposition tool 102, among other examples) depositing an oxide material (e.g., a dielectric material) within such a through-hole to make mechanical contact with a top layer of the first plurality of metal layers 245a.

Additionally, or alternatively, one or more of the semiconductor processing tools 102-114 (e.g., the bonding tool 114, among other examples) may perform a series of operations 450 to form the interconnect structure 280a and 280b. Forming the interconnect structures 280a and 280b may include forming the interconnect structures 280a and 280b through a backside of the substrate 250a.

In some implementations, forming the interconnect structures 280a and 280b includes one or more of the semiconductor processing tools 102-114 (e.g., the exposure tool 104, the developer tool 106, and/or the etch tool 108, among other examples) forming corresponding through-holes that pass through the substrate 250a and the well structure 255a. Forming the interconnect structures 280a and 280b may further include one or more of the semiconductor processing tools 102-114 (e.g., the deposition tool 102, among other examples) depositing an oxide material (e.g., a dielectric material) and a metal material (e.g., a conductive material) within the through-holes to make electrical contact with one or more underlying metal layers in the IC die 205a.

The operations provided by FIGS. 4A-4F are provided as examples. In practice, there may be additional operations, different operations, or differently arranged operations than those illustrated in FIGS. 4A-4F.

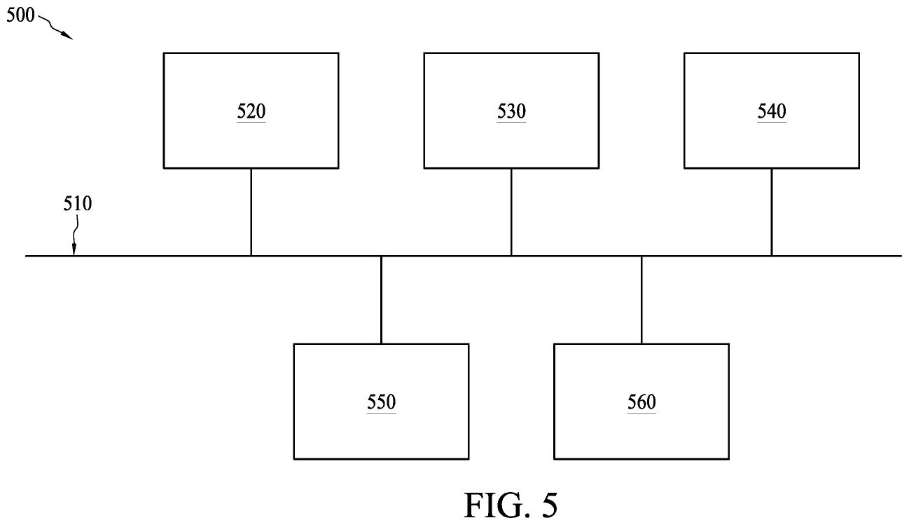

FIG. 5 is a diagram of example components of one or more devices 500 described herein. In some implementations, one or more of the semiconductor processing tools 102-114 and/or the wafer/die transport tool 116 may include one or more devices 500 and/or one or more components of device 500. As illustrated in FIG. 5, device 500 may include a bus 510, a processor 520, a memory 530, an input component 540, an output component 550, and a communication component 560.

Bus 510 includes one or more components that enable wired and/or wireless communication among the components of device 500. Bus 510 may couple together two or more components of FIG. 5, such as via operative coupling, communicative coupling, electronic coupling, and/or electric coupling. Processor 520 includes a central processing unit, a graphics processing unit, a microprocessor, a controller, a microcontroller, a digital signal processor, a field-programmable gate array, an application-specific integrated circuit, and/or another type of processing component. Processor 520 is implemented in hardware, firmware, or a combination of hardware and software. In some implementations, processor 520 includes one or more processors capable of being programmed to perform one or more operations or processes described elsewhere herein.

Memory 530 includes volatile and/or nonvolatile memory. For example, memory 530 may include random access memory (RAM), read only memory (ROM), a hard disk drive, and/or another type of memory (e.g., a flash memory, a magnetic memory, and/or an optical memory). Memory 530 may include internal memory (e.g., RAM, ROM, or a hard disk drive) and/or removable memory (e.g., removable via a universal serial bus connection). Memory 530 may be a non-transitory computer-readable medium. Memory 530 stores information, instructions, and/or software (e.g., one or more software applications) related to the operation of device 500. In some implementations, memory 530 includes one or more memories that are coupled to one or more processors (e.g., processor 520), such as via bus 510.

Input component 540 enables device 500 to receive input, such as user input and/or sensed input. For example, input component 540 may include a touch screen, a keyboard, a keypad, a mouse, a button, a microphone, a switch, a sensor, a global positioning system sensor, an accelerometer, a gyroscope, and/or an actuator. Output component 550 enables device 500 to provide output, such as via a display, a speaker, and/or a light-emitting diode. Communication component 560 enables device 500 to communicate with other devices via a wired connection and/or a wireless connection. For example, communication component 560 may include a receiver, a transmitter, a transceiver, a modem, a network interface card, and/or an antenna.

Device 500 may perform one or more operations or processes described herein. For example, a non-transitory computer-readable medium (e.g., memory 530) may store a set of instructions (e.g., one or more instructions or code) for execution by processor 520. Processor 520 may execute the set of instructions to perform one or more operations or processes described herein. In some implementations, execution of the set of instructions, by one or more processors 520, causes the one or more processors 520 and/or the device 500 to perform one or more operations or processes described herein. In some implementations, hardwired circuitry is used instead of or in combination with the instructions to perform one or more operations or processes described herein. Additionally, or alternatively, processor 520 may be configured to perform one or more operations or processes described herein. Thus, implementations described herein are not limited to any specific combination of hardware circuitry and software.

The number and arrangement of components illustrated in FIG. 5 are provided as an example. Device 500 may include additional components, fewer components, different components, or differently arranged components than those illustrated in FIG. 5. Additionally, or alternatively, a set of components (e.g., one or more components) of device 500 may perform one or more functions described as being performed by another set of components of device 500.

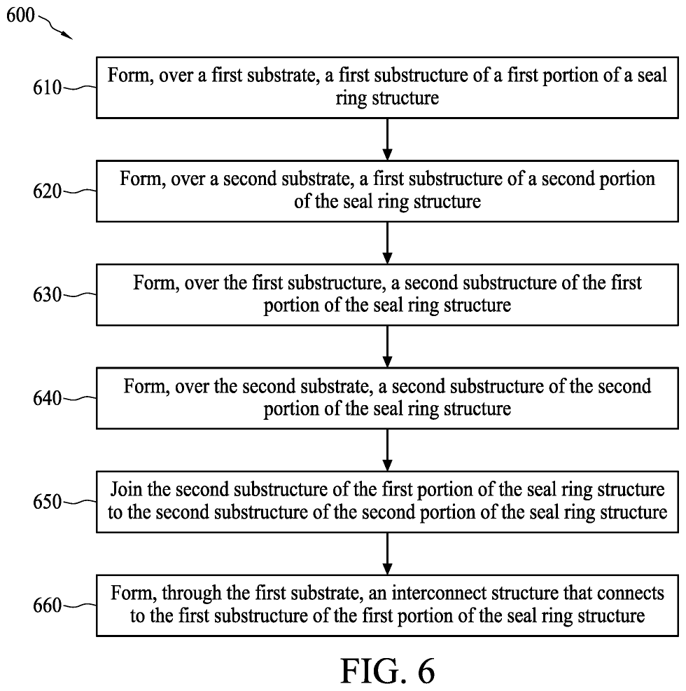

FIG. 6 is a flowchart of an example process 600 associated with a semiconductor structure and methods of formation. In some implementations, one or more process blocks of FIG. 6 are performed by one or more semiconductor processing tools (e.g., one or more of the semiconductor processing tools 102-114). Additionally, or alternatively, one or more process blocks of FIG. 6 may be performed by one or more components of device 500, such as processor 520, memory 530, input component 540, output component 550, and/or communication component 560. The semiconductor structure formed by the process 600 may include one or more features or substructures described in connections with FIGS. 2A-4F.

As illustrated in FIG. 6, process 600 may include forming, over a first substrate, a first substructure of a first portion of a seal ring structure (block 610). For example, one or more of the semiconductor processing tools 102-114 (e.g., one or more of the deposition tool 102, the exposure tool 104, the developer tool 106, or the etch tool 108, among other examples) may form, over a first substrate (e.g., the substrate 250a), a first substructure (e.g., the metal layers 245a) of a first portion (e.g., the portion 295a) of a seal ring structure 295, as described above. In some implementations, forming the first substructure includes forming the first substructure over a first surface of the first substrate.

As further illustrated in FIG. 6, process 600 may include forming, over a second substrate, a first substructure of a second portion of the seal ring structure (block 620). For example, one or more of the semiconductor processing tools 102-114 (e.g., one or more of the deposition tool 102, the exposure tool 104, the developer tool 106, or the etch tool 108, among other examples) may form, over a second substrate (e.g., the substrate 250b), a first substructure (e.g., the metal layers 245b) of a second portion (e.g., the portion 295b) of the seal ring structure 295, as described above.

As further illustrated in FIG. 6, process 600 may include forming, over the first substructure, a second substructure of the first portion of the seal ring structure (block 630). For example, one or more of the semiconductor processing tools 102-114 (e.g., one or more of the deposition tool 102, the exposure tool 104, the developer tool 106, and the etch tool 108, among other examples) may form, over the first substructure, a second substructure of the first portion of the seal ring structure (e.g., a combination of the contact structure 240a and the hybrid bond layer structure 235a), as described above.

As further illustrated in FIG. 6, process 600 may include forming, over the second substrate, a second substructure of the second portion of the seal ring structure (block 640). For example, one or more of the semiconductor processing tools 102-114 (e.g., one or more of the deposition tool 102, the exposure tool 104, the developer tool 106, or the etch tool 108, among other examples) may form, over the second substrate, a second substructure of the second portion of the seal ring structure (e.g., a combination of the hybrid bond contact structure 240b and the hybrid bond layer structure 235b), as described above.

As further illustrated in FIG. 6, process 600 may include joining the second substructure of the first portion of the seal ring structure to the second substructure of the second portion of the seal ring structure (block 650). For example, one or more of the semiconductor processing tools 102-114 (e.g., the bonding tool 114, among other examples) may join the second substructure of the first portion of the seal ring structure to the second substructure of the second portion of the seal ring structure (e.g., join a surface of the hybrid bond layer structure 235a to a surface of the hybrid bond layer structure 235b), as described above.

As further illustrated in FIG. 6, process 600 may include forming, through the first substrate, an interconnect structure that connects to the first substructure of the first portion of the seal ring structure (block 660). For example, one or more of the semiconductor processing tools 102-114 (e.g., one or more of the deposition tool 102, the exposure tool 104, the developer tool 106, or the etch tool 108, among other examples) may form, through the first substrate, an interconnect structure 260 that connects to the first substructure of the first portion of the seal ring structure (e.g., the metal layers 245a) as described above. In some implementations, forming the interconnect structure 260 includes forming the interconnect structure 260 from a second surface of the first substrate that is opposite the first surface.

Process 600 may include additional implementations, such as any single implementation or any combination of implementations described below and/or in connection with one or more other processes described elsewhere herein.

In a first implementation, forming the first substructure of the first portion of the seal ring structure 295 includes forming a vertical stack of a plurality of metal layers (e.g., the metal layers 245a) over the first substrate.

In a second implementation, alone or in combination with the first implementation, forming the second substructure of the first portion of the seal ring structure 295 includes forming a contact structure 240a over the plurality of metal layers 245a, and forming a hybrid bond layer structure 235a over the contact structure 240a.

In a third implementation, alone or in combination with one or more of the first and second implementations, forming the first substructure of the second portion of the seal ring structure 295 includes forming a vertical stack of a plurality of metal layers 245b over the second substrate.

In a fourth implementation, alone or in combination with one or more of the first through third implementations, forming the second substructure of the second portion of the seal ring structure 295 includes forming a hybrid bond contact structure 240b over the plurality of metal layers 245b, and forming a hybrid bond layer structure 235b over the hybrid bond contact structure 240b.

In a fifth implementation, alone or in combination with one or more of the first through fourth implementations, joining the second substructure of the first portion of the seal ring structure 295 to the second substructure of the second portion of the seal ring structure 295 includes joining a hybrid bond layer structure 235a of the first portion of the seal ring structure 295 to a hybrid bond layer structure 235b of the second portion of the seal ring structure 295 using an eutectic bonding process.

In a sixth implementation, alone or in combination with one or more of the first through fifth implementations, forming the interconnect structure 260 that connects to the first substructure of the first portion of the seal ring structure 295 includes forming a through-hole that passes through the first substrate and a well structure (e.g., the well structure 255a) to expose the first substructure, and forming an oxide material within the through-hole.

Although FIG. 6 illustrates example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

Some implementations described herein provide techniques and apparatuses for a stacked-die structure including a first IC die over a second IC die, where an operating voltage of the first IC die is different relative to an operating voltage of the second IC die. The first IC die includes a first portion of a seal ring structure of the stacked die semiconductor package. The first portion includes an interconnect structure (e.g., a backside through silicon via) that connects a backside redistribution layer of the first IC die with first metal layers of the first IC die.

The seal ring structure including the interconnect structure eliminates the use of diodes and electrically isolates well structures of the first IC die to reduce leakage paths within the stacked-die structure relative to a seal ring structure including a diode. Furthermore, use of the interconnect structure as part of the seal ring structure provides for a physical barrier that substantially eliminates moisture and/or cracking from penetrating the stacked-die structure.

In this way, a likelihood of leakage within the stacked-die structure may be reduced relative to a stacked-die structure having a seal ring structure including a diode to improve a performance of the stacked-die structure. Additionally, a physical barrier formed using the interconnect structure as part of the seal ring structure substantially eliminates moisture and/or cracking from penetrating the stacked-die structure improve a yield and/or a reliability of the stacked-die structure.

As described in greater detail above, some implementations described herein provide a semiconductor structure. The semiconductor structure includes a first portion of a seal ring structure. The first portion of the seal ring structure includes an interconnect structure passing through a first substrate and a first well structure of a first IC die, a first plurality of metal layers below the interconnect structure, and a first hybrid bond layer structure below the first plurality of metal layers. The semiconductor structure includes a second portion of the seal ring structure. The second portion of the seal ring structure includes a second plurality of metal layers above a second substrate and a second well structure of a second IC die. The second portion of the seal ring structure includes a second hybrid bond layer structure above the second plurality of metal layers.

As described in greater detail above, some implementations described herein provide a semiconductor structure. The semiconductor structure includes a first IC die including a first substrate, a first ring-shaped well structure below the substrate, and a first portion of a seal ring structure. The first portion of the seal ring structure includes a ring-shaped through-via structure, where the ring-shaped through-via structure penetrates through the first substrate and the first ring-shaped well structure. The semiconductor structure includes a second IC die bonded to the first IC die below the first portion of the seal ring structure. The second IC die includes a second substrate, a second ring-shaped well structure above the second substrate, and a second portion of the seal ring structure. The second portion of the seal ring structure includes ring-shaped contact structures, where the ring-shaped contact structures connect to the second ring-shaped well structure.

As described in greater detail above, some implementations described herein provide a method. The method includes forming, over a first substrate, a first substructure of a first portion of a seal ring structure, where forming the first substructure comprises forming the first substructure over a first surface of the first substrate. The method includes forming, over a second substrate, a first substructure of a second portion of the seal ring structure. The method includes forming, over the first substructure, a second substructure of the first portion of the seal ring structure. The method includes forming, over the second substrate, a second substructure of the second portion of the seal ring structure. The method includes joining the second substructure of the first portion of the seal ring structure to the second substructure of the second portion of the seal ring structure. The method includes forming, through the first substrate, an interconnect structure that connects to the first substructure of the first portion of the seal ring structure, where forming the interconnect structure comprises forming the interconnect structure from a second surface of the first substrate that is opposite the first surface.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first portion of a seal ring structure comprising:
an interconnect structure penetrating through a first substrate and a first well structure of a first integrated circuit die,
a first plurality of metal layers below the interconnect structure, and
a first hybrid bond layer structure below the first plurality of metal layers; and
a second portion of the seal ring structure comprising:
a second plurality of metal layers above a second substrate and a second well structure of a second integrated circuit die, and
a second hybrid bond layer structure above the second plurality of metal layers,
wherein the second hybrid bond layer structure joins with the first hybrid bond layer structure to complete the seal ring structure.

2. The semiconductor structure of claim 1, wherein the first substrate corresponds to a p-type substrate and the first well structure corresponds to a p-type well structure.

3. The semiconductor structure of claim 1, wherein a width of the interconnect structure is included in a range of approximately 2.50 microns to approximately 3.05 microns.

4. The semiconductor structure of claim 1, wherein the interconnect structure comprises:
a dielectric material.

5. The semiconductor structure of claim 1, further comprising:
a ditch structure adjacent to the seal ring structure.

6. The semiconductor structure of claim 1, further comprising:
a redistribution layer above the interconnect structure.

7. The semiconductor structure of claim 6, wherein the interconnect structure is part of a mechanical connection from the redistribution layer to the second substrate.

8. A semiconductor structure, comprising:
a first integrated circuit die comprising:
a first substrate,
a first ring-shaped well structure below the first substrate; and
a first portion of a seal ring structure comprising a ring-shaped through-via structure,
wherein the ring-shaped through-via structure penetrates through the first
substrate and the first ring-shaped well structure; and
a second integrated circuit die bonded to the first integrated circuit die below the first portion of the seal ring structure and comprising:
a second substrate,
a second ring-shaped well structure above the second substrate, and
a second portion of the seal ring structure comprising ring-shaped contact structures,
wherein the ring-shaped contact structures connect to the second ring-shaped well structure.

9. The semiconductor structure of claim 8, wherein the ring-shaped contact structures are between a top surface of the second ring-shaped well structure and a plurality of metal layers of the second portion of the seal ring structure.

10. The semiconductor structure of claim 8, wherein the first portion of the seal ring structure comprises:
a plurality of metal layers, and
wherein the ring-shaped through-via structure connects to a top metal layer of the plurality of metal layers.

11. The semiconductor structure of claim 10, wherein the through-via structure comprises:
a dielectric material.

12. The semiconductor structure of claim 10, wherein the first portion of the seal ring structure further comprises
a hybrid bond layer structure below the plurality of metal layers.

13. The semiconductor structure of claim 12, further comprising:
a hybrid bond contact structure between the hybrid bond layer structure and the plurality of metal layers.

14. A method, comprising:
forming, over a first substrate, a first substructure of a first portion of a seal ring structure,
wherein forming the first substructure comprises forming the first substructure over a first surface of the first substrate;
forming, over a second substrate, a first substructure of a second portion of the seal ring structure;
forming, over the first substructure, a second substructure of the first portion of the seal ring structure;
forming, over the second substrate, a second substructure of the second portion of the seal ring structure;
joining the second substructure of the first portion of the seal ring structure to the second substructure of the second portion of the seal ring structure; and
forming, through the first substrate, an interconnect structure that connects to the first substructure of the first portion of the seal ring structure,
wherein forming the interconnect structure comprises forming the interconnect structure from a second surface of the first substrate that is opposite the first surface.

15. The method of claim 14, wherein forming the first substructure of the first portion of the seal ring structure comprises:
forming a vertical stack of a plurality of metal layers over the first substrate.

16. The method of claim 15, wherein forming the second substructure of the first portion of the seal ring structure comprises:
forming a hybrid bond contact structure over the plurality of metal layers, and
forming a hybrid bond layer structure over the hybrid bond contact structure.

17. The method of claim 14, wherein forming the first substructure of the second portion of the seal ring structure comprises:
forming a vertical stack of a plurality of metal layers over the second substrate.

18. The method of claim 17, wherein forming the second substructure of the second portion of the seal ring structure comprises:
forming a hybrid bond contact structure over the plurality of metal layers, and
forming a hybrid bond layer structure over the hybrid bond contact structure.

19. The method of claim 14, wherein joining the second substructure of the first portion of the seal ring structure to the second substructure of the second portion of the seal ring structure comprises:
joining a hybrid bond layer structure of the first portion of the seal ring structure to a hybrid bond layer structure of the second portion of the seal ring structure using an eutectic bonding process.

20. The method of claim 14, wherein forming the interconnect structure that connects to the first substructure of the first portion of the seal ring structure comprises:
forming a through-hole that passes through the first substrate and a well structure to expose the first substructure, and
forming an oxide material within the through-hole.
